(19) United States
(12) Patent Application Publication
(10) Pub. No.: US 2026/0353715 A1
(43) Pub. Date: Nov. 5, 2026

(54) SEMICONDUCTOR TRANSISTOR USING A MONOLITHICALLY OXIDIZED METAL SCHOTTKY GATE AND METHOD FOR MANUFACTURING THE SAME

(71) Applicant: SEOUL NATIONAL UNIVERSITY R&DB FOUNDATION, Seoul (KR)

(72) Inventors: Chul-Ho LEE, Seoul (KR); Yeon Ho KIM, Seoul (KR)

(21) Appl. No.: 19/719,667

(22) Filed: Jun. 25, 2026

Related U.S. Application Data
(63) Continuation of application No. PCT/KR2024/021300, filed on Dec. 27, 2024.

(30) Foreign Application Priority Data
Dec. 28, 2023 (KR) 10-2023-0194180
Aug. 7, 2024 (KR) 10-2024-0105035

(51) Int. Cl. H10D 30/87; H10D 8/60; H10D 30/01; H10D 62/80

(52) U.S. Cl. CPC H10D 30/87; H10D 30/0614; H10D 30/0616; H10D 62/883; H10D 8/60

(57) ABSTRACT

A semiconductor transistor according to an embodiment comprises: a substrate; a gate layer formed on the substrate; a channel layer formed on the substrate; an insertion layer formed at an interface between the gate layer and the channel layer; and a first electrode and a second electrode respectively coupled to opposite ends of the channel layer, wherein the insertion layer is formed on a surface of the gate layer by a monolithic oxidation process.

### CROSS-REFERENCE TO RELATED APPLICATION

This application is a continuation application of International Patent Application No. PCT/KR 2024/021300, filed on Dec. 27, 2024, which claims priority to and the benefit of Korean Patent Application No. 10-2023-0194180, filed on Dec. 28, 2023, in the Korean Intellectual Property Office, and Korean Patent Application No. 10-2024-0105035, filed on Aug. 7, 2024, in the Korean Intellectual Property Office, the entire contents of which are incorporated herein by reference.

### BACKGROUND

### Technical Field

The present invention relates to a semiconductor transistor using a monolithically oxidized metal Schottky gate and a method for manufacturing the same.

### Background Art

The surface of a two-dimensional semiconductor has almost no dangling bonds. Accordingly, it is difficult to form a uniform thin film even when an atomic layer deposition apparatus used in a conventional transistor process is employed.

In addition, defects generated during a gate dielectric deposition process may cause problems such as hysteresis and subthreshold swing of a transistor.

Accordingly, a MESFET structure using a Schottky junction has a high capacitance and can solve problems occurring in a gate dielectric. However, the MESFET structure has a problem in that implementation thereof is difficult due to a Fermi-level pinning phenomenon at a two-dimensional semiconductor-metal junction.

Therefore, in the present invention, a Schottky gate having a depinned Fermi level at a metal-semiconductor junction is formed through a monolithic oxidation process of a three-dimensional metal gate. Through the formation of such a Schottky gate, an n-type transistor approaching the Boltzmann switching limit is intended to be provided.

In this regard, as a prior art document, Korean Patent Registration No. 10-1056221 (Title of Invention: Integrated Low-Leakage Schottky Diode) is disclosed.

### SUMMARY

### Problem to Be Solved

The present invention aims to provide a semiconductor transistor using a Schottky gate having a depinned Fermi level at a metal-semiconductor junction through a monolithic oxidation process of a three-dimensional metal gate, and a method for manufacturing the same, in order to solve the above-described problems.

However, the technical problem to be achieved by the present embodiment is not limited to the technical problems described above, and other technical problems may also exist.

### Means for Solving the Problem

According to a first aspect of the present invention, a semiconductor transistor comprises: a substrate; a gate layer formed on the substrate; a channel layer formed on the gate layer; an insertion layer formed at an interface between the gate layer and the channel layer; and a first electrode and a second electrode respectively coupled to opposite ends of the channel layer, wherein the insertion layer is formed on a surface of the gate layer by a monolithic oxidation process.

According to a second aspect of the present invention, a semiconductor transistor comprises: a substrate; a channel layer formed on the substrate; a gate layer formed on the channel layer; an insertion layer formed at an interface between the gate layer and the channel layer; and a first electrode and a second electrode respectively coupled to opposite ends of the channel layer, wherein the insertion layer is formed by oxidizing a gate metal layer through an oxidation process.

According to a third aspect of the present invention, a method for manufacturing a semiconductor transistor comprises: providing a channel layer; forming a gate layer on a substrate; forming an insertion layer by oxidizing a surface of the gate layer using a monolithic oxidation process; disposing the channel layer on the insertion layer; and forming a first electrode and a second electrode respectively coupled to opposite ends of the channel layer.

According to a fourth aspect of the present invention, a method for manufacturing a semiconductor transistor comprises: forming a channel layer on a substrate; forming a first electrode and a second electrode respectively coupled to opposite ends of the channel layer; forming a gate metal layer on the channel layer; forming an insertion layer by oxidizing the gate metal layer using an oxidation process; and forming a gate layer on the insertion layer.

### Effects of the Invention

According to one embodiment of the present invention, an insertion layer is formed using a three-dimensional metal gate structure. Metal-Induced Gap States (MIGS) are suppressed by the insertion layer, and a Schottky junction may be formed at the interface. Accordingly, switching at a low voltage is enabled. In addition, a threshold voltage may be adjusted according to a work function of a gate electrode. By adjusting the threshold voltage, operation of a depletion mode and an enhancement mode of the transistor may be controlled.

In addition, unlike a conventional MESFET, the present invention uses a monolithically surface-oxidized gate rather than a direct metal-semiconductor junction. An insertion layer formed by the monolithically surface-oxidized gate provides an effect of reducing gate leakage current.

Furthermore, one embodiment of the present invention may operate as a transistor switched by a van der Waals Schottky gate. In addition, the semiconductor device may also operate as a Schottky diode. Accordingly, various functions may be implemented within a single device.

### BRIEF DESCRIPTION OF THE DRAWINGS

FIG. 1 is a diagram illustrating a semiconductor transistor according to an embodiment of the present invention.

FIG. 2 is a cross-sectional view of a semiconductor transistor according to another embodiment of the present invention.

FIG. 3 is an exemplary diagram illustrating a band alignment structure of a semiconductor transistor according to an embodiment of the present invention.

FIG. 4 is a flowchart illustrating a method for manufacturing a semiconductor transistor according to an embodiment of the present invention.

FIGS. 5A to 5F are diagrams illustrating an embodiment of the method for manufacturing the semiconductor transistor of FIG. 4.

FIG. 6 is a flowchart illustrating a method for manufacturing a semiconductor transistor according to another embodiment of the present invention.

FIGS. 7A to 7E are diagrams illustrating an embodiment of the method for manufacturing the semiconductor transistor of FIG. 6.

FIGS. 8A to 12B are diagrams for explaining characteristics of a semiconductor transistor manufactured according to an embodiment of the present invention. FIG. 8A is a graph showing transfer characteristics (Id-Vg characteristics) of a bottom-gate-structured MESFET (Metal-Semiconductor Field-Effect Transistor) according to an embodiment of the present invention. FIG. 8B is a graph showing transfer characteristics (Id-Vg characteristics) of a top-gate-structured MESFET according to another embodiment of the present invention. FIG. 9 is a graph showing voltage transfer characteristics of an inverter composed of Schottky-gate-based two-dimensional semiconductor transistors. FIG. 10 is a graph showing rectification characteristics (diode characteristics) of the semiconductor transistor according to the present invention. FIG. 11 is a graph showing changes in threshold voltage of the semiconductor transistor according to the present invention according to a type of gate metal. FIG. 12A is a graph showing output characteristics of a large-area MoS₂ MESFET array according to the present invention. FIG. 12B is a graph showing transfer characteristics of a single MoS₂ MESFET according to the present invention.

### DETAILED DESCRIPTION

Hereinafter, embodiments of the present invention will be described in detail with reference to the accompanying drawings so that those skilled in the art can easily carry out the invention. However, the present invention may be embodied in various different forms and is not limited to the embodiments described herein. In the drawings, portions unrelated to the description are omitted for clarity of explanation, and like reference numerals denote like elements throughout the specification.

Throughout the specification, when a portion is described as being “connected” to another portion, this includes not only a case in which the portion is “directly connected” thereto but also a case in which the portion is “electrically connected” thereto with another element interposed therebetween. In addition, when a portion is described as “including” a component, this means that the portion may further include other components rather than excluding other components unless specifically stated otherwise, and should be understood as not precluding the presence or addition of one or more other features, numbers, steps, operations, components, parts, or combinations thereof.

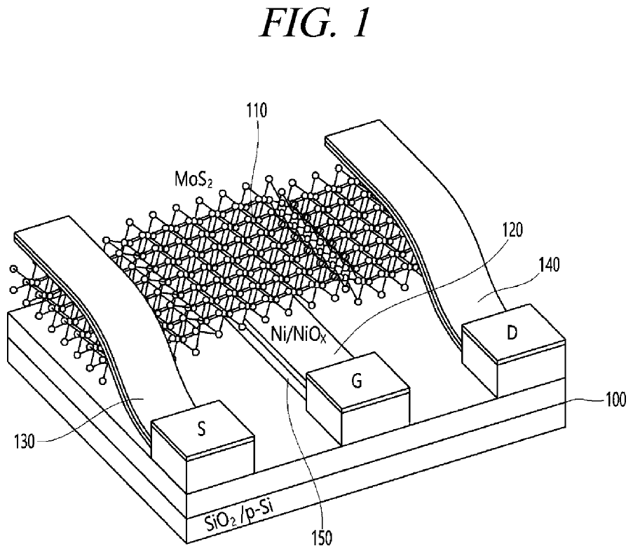

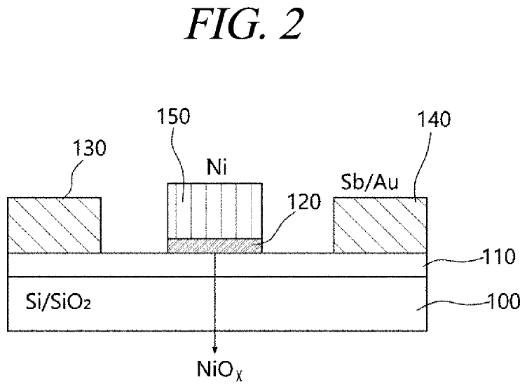

FIG. 1 is a diagram illustrating a semiconductor transistor according to an embodiment of the present invention, and FIG. 2 is a cross-sectional view of a semiconductor transistor according to another embodiment of the present invention.

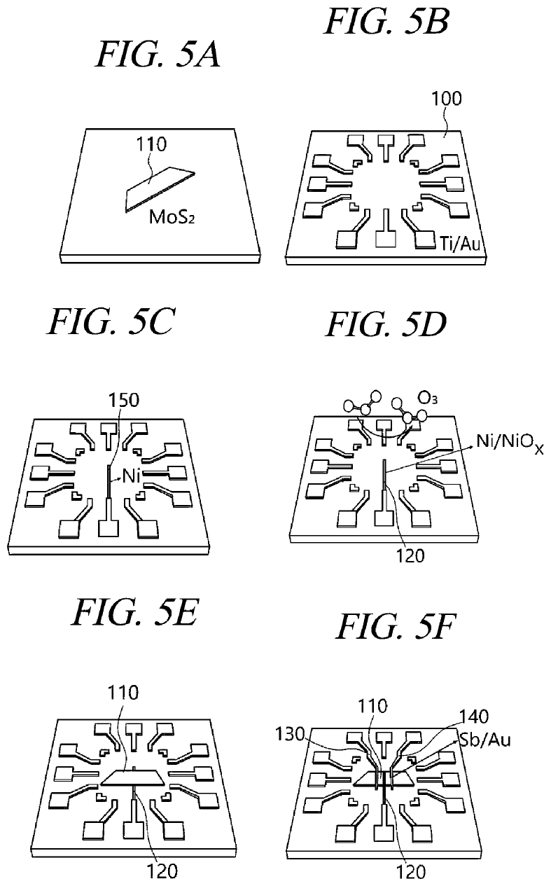

Referring to FIG. 1, the semiconductor transistor includes a substrate 100, a gate layer 150 formed on the substrate 100, a channel layer 110 formed on the gate layer 150, an insertion layer 120 formed at an interface between the gate layer 150 and the channel layer 110, and a first electrode 130 and a second electrode 140 respectively coupled to opposite ends of the channel layer 110. Here, a method of forming the insertion layer 120 on a surface of the gate layer 150 by a monolithic oxidation process will be described later in detail with reference to FIG. 5.

Referring to FIG. 2, the semiconductor transistor includes a substrate 100, a channel layer 110 formed on the substrate 100, a gate layer 150 formed on the channel layer 110, an insertion layer 120 formed at an interface between the gate layer 150 and the channel layer 110, and a first electrode 130 and a second electrode 140 respectively coupled to opposite ends of the channel layer 110. In this case, the insertion layer 120 is formed on one surface of the gate layer 150 by a monolithic oxidation process.

For example, the gate layer 150 may be formed below the channel layer 110 or above the channel layer 110. For example, the gate layer 150 may be made of a metal such as Ni or Cu, but is not limited thereto.

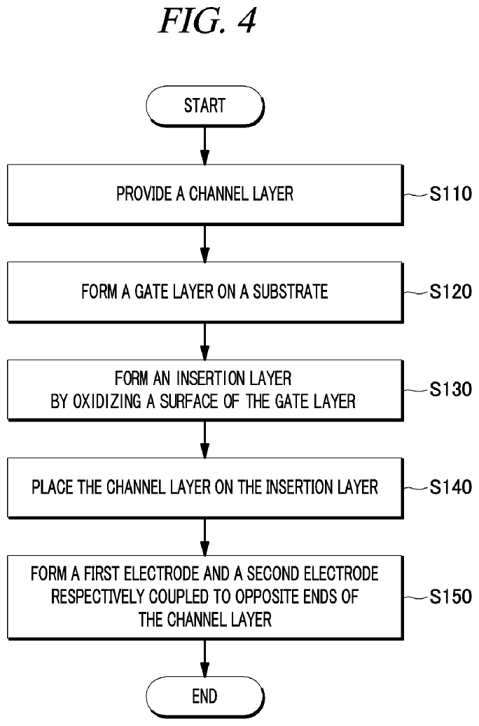

As an example, as shown in FIG. 1, the semiconductor transistor may be formed in a bottom-gate structure in which the gate layer 150, the insertion layer 120, and the channel layer 110 are sequentially stacked on the substrate 100. A method for manufacturing such a bottom-gate structure will be described later with reference to FIG. 4.

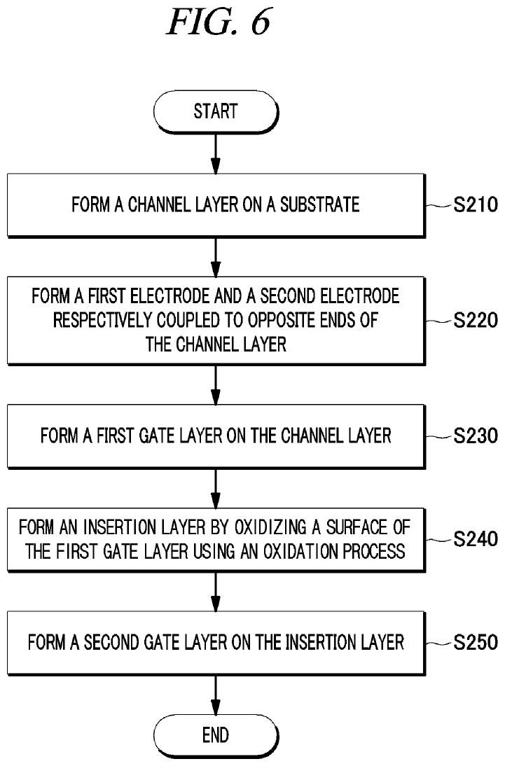

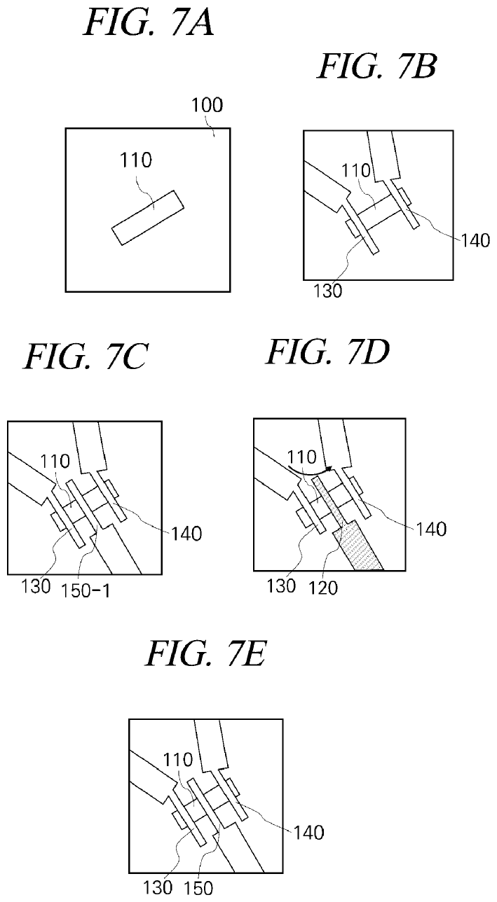

According to another example, as shown in FIG. 2, the semiconductor transistor has a structure in which a channel layer 110, an insertion layer 120, and a gate layer 150 are sequentially stacked on a substrate 100. Through such a stacked structure, the semiconductor transistor may be formed in a top-gate structure. A method for manufacturing such a top-gate structure will be described later with reference to FIGS. 6 and 7.

For example, the channel layer 110 may include at least one material selected from the group consisting of transition metal chalcogen compounds including MoS₂, MoSe₂, MoTe₂, WS₂, WSe₂, WTe₂, Bi₂O₂Se, InSe, In₂Se₃, PdS₂, PdSe₂, HfS₂, HfSe₂, ZrS₂, and ZrSe₂.

In addition, the first electrode 130 and the second electrode 140 are respectively coupled to opposite ends of the channel layer 110 and may serve as a source electrode and a drain electrode. Meanwhile, a separate gate electrode may be connected to one side of the gate layer 150. For example, each electrode may be made of a metal such as Sb, Au, Ti, Cr, Bi, or Al, but is not limited thereto.

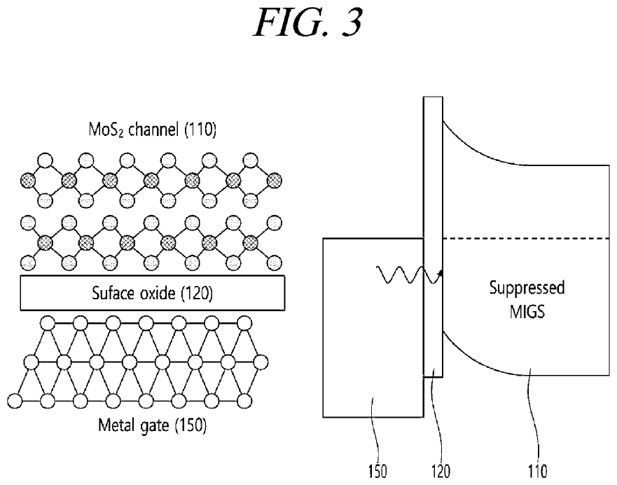

FIG. 3 is an exemplary diagram illustrating a band alignment structure of a semiconductor transistor according to an embodiment of the present invention.

Referring to FIG. 3, the insertion layer 120 is an oxide layer formed on a surface of the gate layer 150 through a monolithic oxidation process. The insertion layer 120 may serve to suppress transmission of an electron wave function from the gate layer 150 to the channel layer 110.

For example, the insertion layer 120 is formed between the gate layer 150 and the channel layer 110. By virtue of such an arrangement, the insertion layer 120 may prevent the electron wave function from penetrating into the semiconductor bandgap. That is, the electron wave function is blocked by the insertion layer 120. As a result of such blocking, Metal-Induced Gap States (MIGS) are suppressed. Further, suppression of the Metal-Induced Gap States may alleviate a Fermi-level pinning phenomenon. Accordingly, the intrinsic electrical characteristics of the semiconductor may be maintained, and device performance may be improved.

FIG. 4 is a flowchart illustrating a method for manufacturing a semiconductor transistor according to an embodiment of the present invention, and FIGS. 5A to 5F are diagrams illustrating an embodiment of the method for manufacturing the semiconductor transistor of FIG. 4.

Referring to FIG. 4, the method for manufacturing a semiconductor transistor according to an embodiment of the present invention includes providing a channel layer 110 (S110), forming a gate layer 150 on a substrate 100 (S120), forming an insertion layer 120 by oxidizing a surface of the gate layer 150 using a monolithic oxidation process (S130), disposing the channel layer 110 on the insertion layer 120 (S140), and forming a first electrode 130 and a second electrode 140 respectively coupled to opposite ends of the channel layer 110 (S150). Here, the insertion layer 120 may be an oxide layer configured to suppress transmission of an electron wave function from the gate layer 150 to the channel layer 110.

For example, referring to FIG. 5A, in the method for manufacturing a semiconductor transistor having a bottom-gate structure, a channel layer 110 made of MoS₂ may be provided. Referring to FIG. 5B, in order to form the gate layer 150, a substrate 100 provided with a conventional patterned electrode may be used. In this case, the structure of the patterned electrode is merely an example and is not limited thereto. Thereafter, referring to FIG. 5C, the gate layer 150 may be formed on the substrate 100 through lithography and deposition processes. Subsequently, referring to FIG. 5D, the surface of the gate layer 150 is oxidized by ozone treatment performed over the entire surface at 150 °C for 30 minutes. Through such surface oxidation, the insertion layer 120 may be formed. That is, the insertion layer 120 may be an oxide layer formed by monolithic oxidation of a portion of the surface of the gate layer 150 before the oxidation process. After the oxidation process shown in FIG. 5D, the channel layer 110 may be transferred onto the insertion layer 120 using a PPC (polypropylene carbonate)/PDMS (polydimethylsiloxane) stamp. In this case, the gate layer 150 shown in FIG. 5C may have a structure in which the insertion layer 120 is stacked on the gate layer 150, as shown in FIG. 5E. Thereafter, referring to FIG. 5F, a first electrode 130 and a second electrode 140, serving as source/drain electrodes, may be formed on opposite ends of the channel layer 110 through lithography and deposition processes. Accordingly, as shown in FIG. 1, the semiconductor transistor having the bottom-gate structure may have a structure in which the gate layer 150, the insertion layer 120, and the channel layer 110 are sequentially stacked on the substrate 100.

FIG. 6 is a flowchart illustrating a method for manufacturing a semiconductor transistor according to another embodiment of the present invention, and FIGS. 7A to 7E are diagrams illustrating an embodiment of the method for manufacturing the semiconductor transistor of FIG. 6.

Referring to FIG. 6, the method for manufacturing a semiconductor transistor according to another embodiment of the present invention includes forming a channel layer 110 on a substrate 100 (S210), forming a first electrode 130 and a second electrode 140 respectively coupled to opposite ends of the channel layer 110 (S220), forming a gate metal layer 150-1 on the channel layer 110 (S230), forming an insertion layer 120 by oxidizing the gate metal layer 150-1 using an oxidation process (S240), and forming a gate layer 150 on the insertion layer 120 (S250). Here, the insertion layer 120 may be an oxide layer configured to suppress transmission of an electron wave function from the gate layer 150 to the channel layer 110.

For example, referring to FIG. 7A, in the method for manufacturing a semiconductor transistor having a top-gate structure, the channel layer 110 may be formed on the substrate 100. Referring to FIG. 7B, a first electrode 130 and a second electrode 140, serving as source/drain electrodes, may be formed on opposite ends of the channel layer 110 through lithography and deposition processes. Thereafter, referring to FIG. 7C, a gate metal layer 150-1 may be formed on the channel layer 110 through lithography and deposition processes. Subsequently, referring to FIG. 7D, the gate metal layer 150-1 may be oxidized using an oxidation process to form the insertion layer 120. In this case, the oxidation process includes an oxygen plasma process or an ozone treatment process, but is not limited thereto. That is, the insertion layer 120 may be an oxide layer formed by oxidation of the gate metal layer 150-1 through the oxidation process. Next, as shown in FIG. 7E, the gate layer 150 may be formed on the insertion layer 120 through lithography and deposition processes. Accordingly, as shown in FIG. 2, the semiconductor transistor having the top-gate structure may have a structure in which the channel layer 110, the insertion layer 120, and the gate layer 150 are sequentially stacked on the substrate 100.

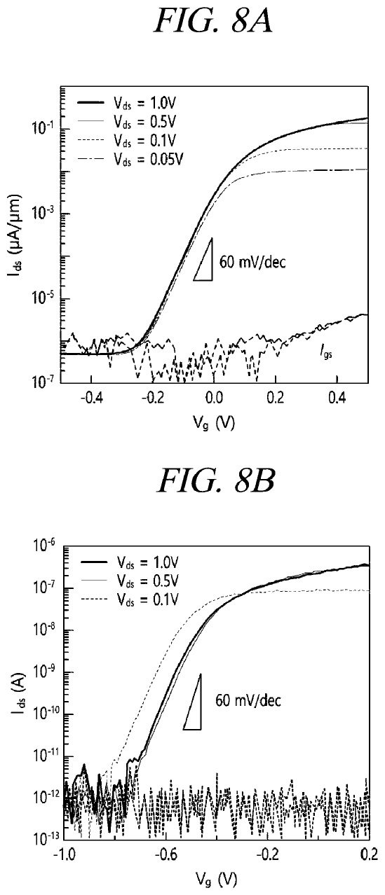

FIGS. 8A to 12B are diagrams for explaining characteristics of a semiconductor transistor manufactured according to an embodiment of the present invention.

FIG. 8A shows transfer characteristics (Id-Vg characteristics) of a MESFET (Metal-Semiconductor Field-Effect Transistor) having a bottom-gate structure according to an embodiment of the present invention, and FIG. 8B shows transfer characteristics (Id-Vg characteristics) of a MESFET having a top-gate structure according to another embodiment of the present invention.

As shown in FIG. 8A, the semiconductor transistor according to the present invention exhibits on/off switching at a gate voltage within 0.5 V. In particular, a Subthreshold Swing (SS) approaching the Boltzmann limit (60 mV/dec) at room temperature exhibits a subthreshold slope. In addition, when a Cu electrode (shown in FIG. 8B) having a lower work function than a Ni electrode (shown in FIG. 8A) is used, the magnitude of a Schottky barrier formed at the interface between the channel layer and the gate metal is reduced, whereby the threshold voltage shifts in a negative direction while demonstrating that the same operation can also be achieved using the Cu electrode.

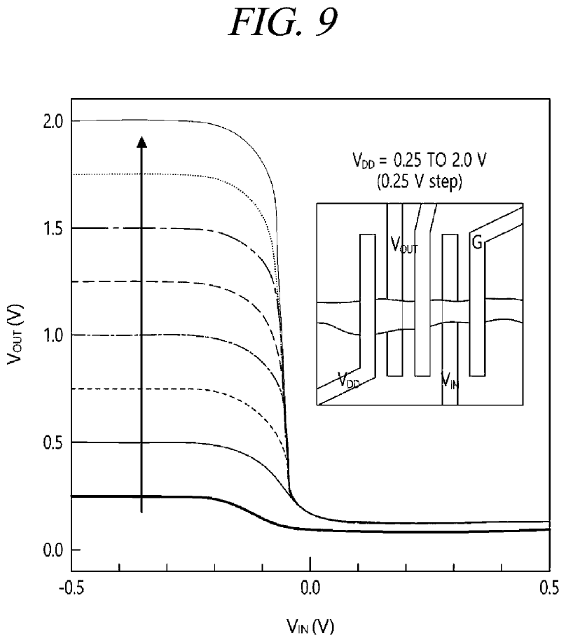

Referring to FIG. 9, voltage transfer characteristics of an inverter composed of Schottky-gate-based two-dimensional semiconductor transistors are shown. That is, an n-type transistor-based inverter fabricated by connecting semiconductor transistors in series exhibits a characteristic in which an output voltage changes as a VDD value increases, and exhibits a voltage gain of 40 V/V at VDD=2 V.

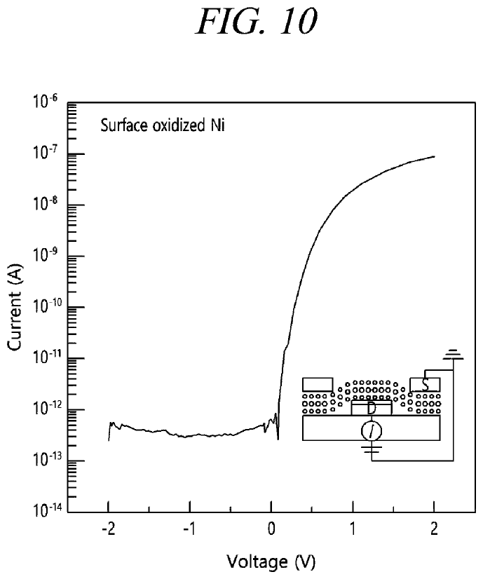

Referring to FIG. 10, the semiconductor transistor according to the present invention can perform functions of both a transistor and a diode. That is, since the semiconductor transistor has a device structure in which a Schottky electrode is used as a gate and is also operable as a Schottky diode, diode characteristics exhibiting rectification characteristics were also confirmed.

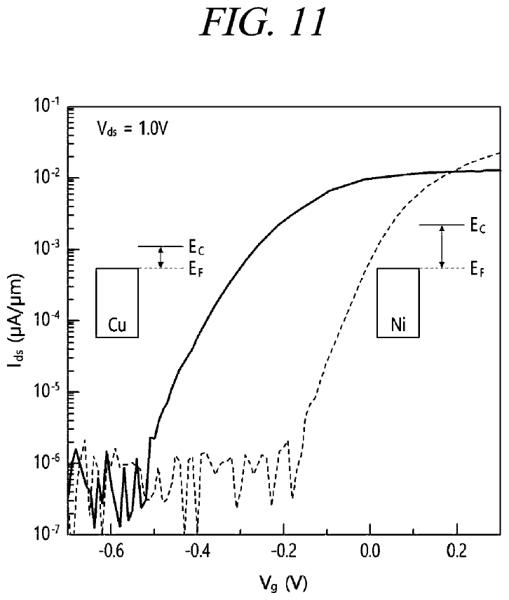

Referring to FIG. 11, the manner in which the threshold voltage of the semiconductor transistor according to the present invention varies according to a type of gate metal is illustrated. A transistor using a Cu gate exhibits a threshold voltage at a lower gate voltage. In addition, a voltage range at which current begins to increase sharply in the transistor using the Cu gate is lower than that of a transistor using Ni. This is because Cu forms a lower Schottky barrier than Ni. That is, formation of such a low Schottky barrier lowers the threshold voltage of the transistor using the Cu gate. In a transistor using a Ni gate, current begins to increase at a somewhat higher gate voltage. This indicates that Ni forms a higher Schottky barrier than Cu, resulting in a higher threshold voltage. That is, by adjusting the threshold voltage of the transistor, a depletion mode and an enhancement mode of the transistor may be controlled using a metal-semiconductor junction having a depinned Fermi level.

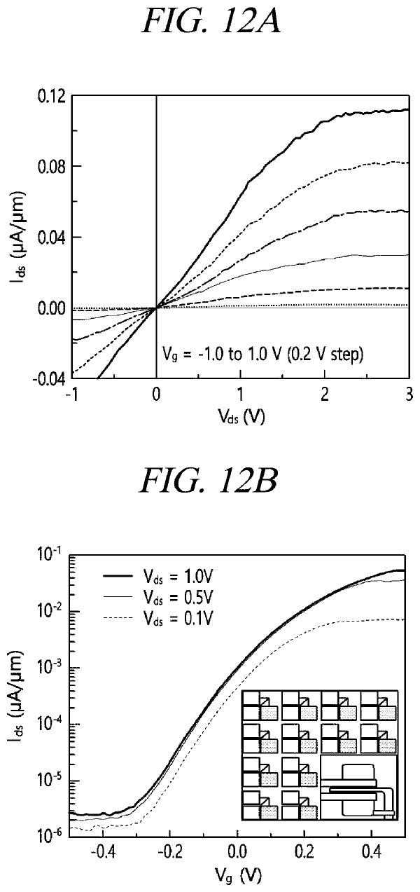

FIG. 12A shows output characteristics of a large-area MoS₂ MESFET array according to the present invention, and FIG. 12B shows transfer characteristics of a single MoS₂ MESFET according to the present invention. That is, in order to confirm uniform device characteristics over a large area, array devices were fabricated using a MoS₂ film synthesized by a chemical vapor deposition (CVD) method, and characteristic evaluation confirmed performance similar to that of a unit device.

The foregoing description of the present invention is provided for illustrative purposes, and those skilled in the art will understand that various modifications may be readily made in other specific forms without departing from the technical spirit or essential characteristics of the present invention. Therefore, the embodiments described above should be understood in all respects as illustrative and not restrictive. For example, each component described as a single entity may be implemented in a distributed manner, and likewise, components described as being distributed may be implemented in a combined form.

The scope of the present invention is defined by the claims set forth below rather than by the foregoing detailed description, and all modifications or variations derived from the meaning and scope of the claims and their equivalents should be construed as being included within the scope of the present invention.

What is claimed is:

1. A semiconductor transistor comprising:
a substrate;
a gate layer formed on the substrate;
a channel layer formed on the gate layer;
an insertion layer formed at an interface between the gate layer and the channel layer; and
a first electrode and a second electrode respectively coupled to opposite ends of the channel layer,
wherein the insertion layer is formed on one surface of the gate layer by a monolithic oxidation process.

2. The semiconductor transistor of claim 1,
wherein the insertion layer is an oxide layer configured to suppress transmission of an electron wave function from the gate layer to the channel layer.

3. The semiconductor transistor of claim 1,
wherein the channel layer includes at least one material selected from the group consisting of transition metal chalcogen compounds including MoS₂, MoSe₂, MoTe₂, WS₂, WSe₂, WTe₂, Bi₂O₂Se, InSe, In₂Se₃, PdS₂, PdSe₂, HfS₂, HfSe₂, ZrS₂, and ZrSe₂.

4. A semiconductor transistor comprising:
a substrate;
a channel layer formed on the substrate;
a gate layer formed on the channel layer;
an insertion layer formed at an interface between the gate layer and the channel layer; and
a first electrode and a second electrode respectively coupled to opposite ends of the channel layer,
wherein the insertion layer is formed by oxidation of a gate metal layer through an oxidation process.

5. The semiconductor transistor of claim 4,
wherein the insertion layer is an oxide layer configured to suppress transmission of an electron wave function from the gate layer to the channel layer.

6. The semiconductor transistor of claim 4,
wherein the channel layer includes at least one material selected from the group consisting of transition metal chalcogen compounds including MoS₂, MoSe₂, MoTe₂, WS₂, WSe₂, WTe₂, Bi₂O₂Se, InSe, In₂Se₃, PdS₂, PdSe₂, HfS₂, HfSe₂, ZrS₂, and ZrSe₂.

7. A method for manufacturing a semiconductor transistor, comprising:
providing a channel layer;
forming a gate layer on a substrate;
forming an insertion layer by oxidizing a surface of the gate layer using a monolithic oxidation process;
disposing the channel layer on the insertion layer; and
forming a first electrode and a second electrode respectively coupled to opposite ends of the channel layer.

8. The method for manufacturing a semiconductor transistor of claim 7,
wherein the insertion layer is an oxide layer configured to suppress transmission of an electron wave function from the gate layer to the channel layer.

9. The method for manufacturing a semiconductor transistor of claim 7,
wherein the channel layer includes at least one material selected from the group consisting of transition metal chalcogen compounds including MoS₂, MoSe₂, MoTe₂, WS₂, WSe₂, WTe₂, Bi₂O₂Se, InSe, In₂Se₃, PdS₂, PdSe₂, HfS₂, HfSe₂, ZrS₂, and ZrSe₂.

10. A method for manufacturing a semiconductor transistor, comprising:
forming a channel layer on a substrate;
forming a first electrode and a second electrode respectively coupled to opposite ends of the channel layer;
forming a gate metal layer on the channel layer;
forming an insertion layer by oxidizing the gate metal layer using an oxidation process;
and forming a gate layer on the insertion layer.

11. The method for manufacturing a semiconductor transistor of claim 10,
wherein the insertion layer is an oxide layer configured to suppress transmission of an electron wave function from the gate layer to the channel layer.

12. The method for manufacturing a semiconductor transistor of claim 10,
wherein the channel layer includes at least one material selected from the group consisting of transition metal chalcogen compounds including MoS₂, MoSe₂, MoTe₂, WS₂, WSe₂, WTe₂, Bi₂O₂Se, InSe, In₂Se₃, PdS₂, PdSe₂, HfS₂, HfSe₂, ZrS₂, and ZrSe₂.
